(19) United States
(12) Patent Application Publication
(10) Pub. No.: US 2008/0232450 A1
(43) Pub. Date: Sep. 25, 2008

(54) METHOD AND APPARATUS FOR ROBUST FREQUENCY EQUALIZATION

(75) Inventor: Qin Liu, FREMONT, CA (US)

Correspondence Address: FRANKLIN (LIN) YANG, 91 CANTERBURY GATE, LYNBROOK, NY, 11563, US

(73) Assignee: LEGEND SILICON CORP., FREMONT, CA (US)

(21) Appl. No.: 11/687,693

(22) Filed: Mar. 19, 2007

(51) Int. Cl. H03K 5/159

(52) U.S. Cl. 375/230

(57) ABSTRACT

In frequency equalization, a received signals goes through frequency transform, the transformed signal is divided by a frequency transform of a channel response a method for equalization. The method comprises the step of: adjusting a quotient of the division by a weight function, wherein the function varies under a set of conditions; whereby for a frequency selective channel, deep fades are adjusted, and noise or interference are reduced.

### FIELD OF THE INVENTION

The present invention relates generally to frequency equalization, more specifically the present invention relates to robust frequency equalization to avoid noise enhancement.

### BACKGROUND

In frequency equalization, received signal goes through frequency transform (DFT or FFT) and are divided by the frequency transform of the channel response. For a frequency selective channel, its frequency response may undergo deep fades, whereas on the other hand division enhances noise or interference.

Therefore, there is a need for an improved equalizer to avert the above drawbacks.

### SUMMARY OF THE INVENTION

In frequency equalization, a different weight is added under a set of different conditions.

In a single carrier application, a different weight is added under a set of different conditions in a frequency equalization.

In frequency equalization, a received signals goes through frequency transform, the transformed signal is divided by a frequency transform of a channel response a method for equalization. The method comprises the step of: adjusting a quotient of the division by a weight function, wherein the function varies under a set of conditions; whereby for a frequency selective channel, deep fades are adjusted, and noise or interference are reduced.

A receiver is provided containing the above mentioned method for equalization.

### BRIEF DESCRIPTION OF THE FIGURES

The accompanying figures, where like reference numerals refer to identical or functionally similar elements throughout the separate views and which together with the detailed description below are incorporated in and form part of the specification, serve to further illustrate various embodiments and to explain various principles and advantages all in accordance with the present invention.

FIG. 1 is an example of a typical equalizer.

FIG. 2 is an example an equalizer in accordance with some embodiments of the invention.

Skilled artisans will appreciate that elements in the figures are illustrated for simplicity and clarity and have not necessarily been drawn to scale. For example, the dimensions of some of the elements in the figures may be exaggerated relative to other elements to help to improve understanding of embodiments of the present invention.

### DETAILED DESCRIPTION

Before describing in detail embodiments that are in accordance with the present invention, it should be observed that the embodiments reside primarily in combinations of method steps and apparatus components related to a different weight is added under a set of different conditions in a frequency equalization. Accordingly, the apparatus components and method steps have been represented where appropriate by conventional symbols in the drawings, showing only those specific details that are pertinent to understanding the embodiments of the present invention so as not to obscure the disclosure with details that will be readily apparent to those of ordinary skill in the art having the benefit of the description herein.

In this document, relational terms such as first and second, top and bottom, and the like may be used solely to distinguish one entity or action from another entity or action without necessarily requiring or implying any actual such relationship or order between such entities or actions. The terms “comprises,” “comprising,” or any other variation thereof, are intended to cover a non-exclusive inclusion, such that a process, method, article, or apparatus that comprises a list of elements does not include only those elements but may include other elements not expressly listed or inherent to such process, method, article, or apparatus. An element proceeded by “comprises . . . a” does not, without more constraints, preclude the existence of additional identical elements in the process, method, article, or apparatus that comprises the element.

It will be appreciated that embodiments of the invention described herein may be comprised of one or more conventional processors and unique stored program instructions that control the one or more processors to implement, in conjunction with certain non-processor circuits, some, most, or all of the functions of a different weight is added under a set of different conditions in a frequency equalization described herein. The non-processor circuits may include, but are not limited to, a radio receiver, a radio transmitter, signal drivers, clock circuits, power source circuits, and user input devices. As such, these functions may be interpreted as steps of a method to perform a different weight is added under a set of different conditions in a frequency equalization. Alternatively, some or all functions could be implemented by a state machine that has no stored program instructions, or in one or more application specific integrated circuits (ASICs), in which each function or some combinations of certain of the functions are implemented as custom logic. Of course, a combination of the two approaches could be used. Thus, methods and means for these functions have been described herein. Further, it is expected that one of ordinary skill, notwithstanding possibly significant effort and many design choices motivated by, for example, available time, current technology, and economic considerations, when guided by the concepts and principles disclosed herein will be readily capable of generating such software instructions and programs and ICs with minimal experimentation.

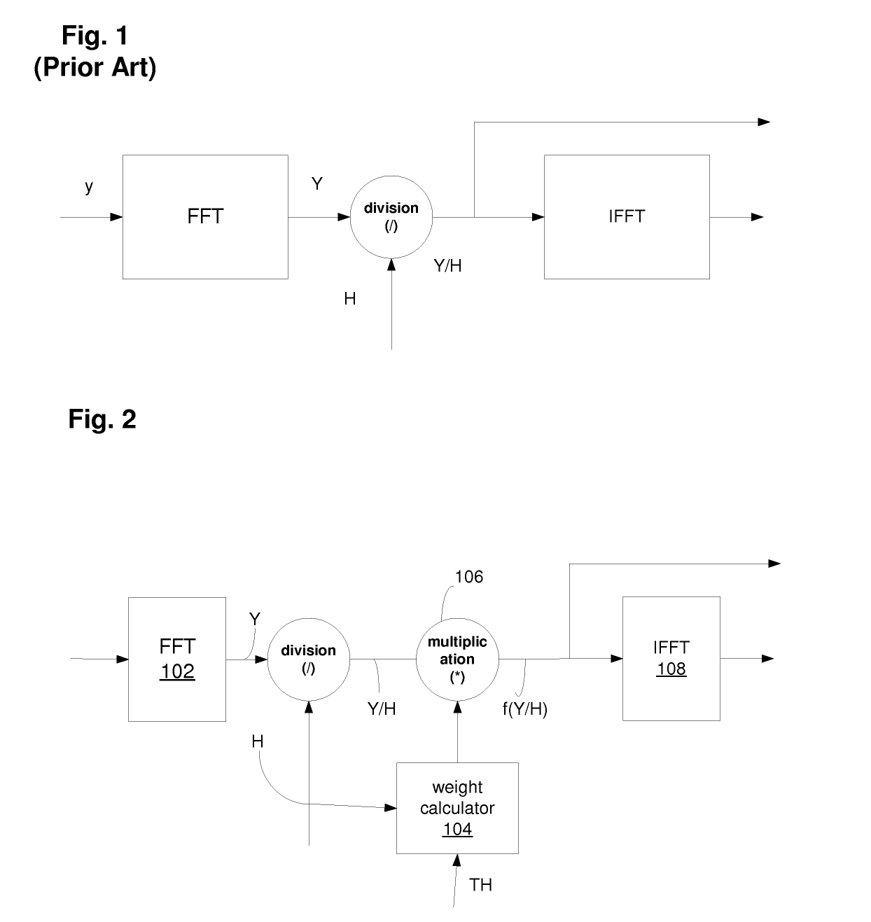

FIG. 1 shows a general frequency equalizer for such devices as a digital receiver. In a typical frequency equalization, the received signal y goes through frequency transform (DFT or FFT) and are divided by the frequency transform H of the channel response. For multi-carrier applications, the quotient of the division is directly used. For single carrier applications, the quotient of the division further goes through an inverse Fourier transformation into the time domain. However, for frequency selective channels, the frequency response may undergo deep fades. On the other hand, the above division action enhances noise or interference.

FIG. 2 comprises a modified frequency equalizer 100. The received signal y goes through frequency transform 102 (DFT or FFT). The transformed information Y is divided by the frequency transform H of the channel response. As is known, for frequency selective channels, the frequency response may undergo deep fades. On the other hand, the above division action enhances noise or interference. Therefore, a weight calculator 104 is provided to carry out a weight calculating operation. Basically, Y/H is weighted according to the relative strength of local |Hᵢ| by averaging same in that if H has n points the weight equals (1/i)avg(Hi) for i=1, . . . , n. if the relative strength is much less, weight of less than 1 is used. Otherwise, eight is 1 meaning no weight is added. The calculation is as follows:

0, if |H|<Th₀;

(|H|/Th₁)^{b} if Th₀<|H|<Th₁

1 if |H|>Th₁

|H|, Th₀ and Th₁ satisfies the following conditions

Th₀<Th₁<avg|H|

A weighted value subject to the mentioned conditions is chosen. The chosen value multiplies the quotient Y/H 106, resulting in a function of Y/H or f(Y/H). For multi-carrier applications, the function is directly used. For single carrier applications, the function further goes through an inverse Fourier transformation into the time domain. The present invention contemplates using the equalizer 100 in an orthogonal frequency division multiplex (OFDM) context.

In the foregoing specification, specific embodiments of the present invention have been described. However, one of ordinary skill in the art appreciates that various modifications and changes can be made without departing from the scope of the present invention as set forth in the claims below. Accordingly, the specification and figures are to be regarded in an illustrative rather than a restrictive sense, and all such modifications are intended to be included within the scope of present invention. The benefits, advantages, solutions to problems, and any element(s) that may cause any benefit, advantage, or solution to occur or become more pronounced are not to be construed as a critical, required, or essential features or elements of any or all the claims. The invention is defined solely by the appended claims including any amendments made during the pendency of this application and all equivalents of those claims as issued.

Terms and phrases used in this document, and variations thereof, unless otherwise expressly stated, should be construed as open ended as opposed to limiting. As examples of the foregoing: the term “including” should be read as mean “including, without limitation” or the like; the term “example” is used to provide exemplary instances of the item in discussion, not an exhaustive or limiting list thereof; and adjectives such as “conventional,” “traditional,” “normal,” “standard,” and terms of similar meaning should not be construed as limiting the item described to a given time period or to an item available as of a given time, but instead should be read to encompass conventional, traditional, normal, or standard technologies that may be available now or at any time in the future. Likewise, a group of items linked with the conjunction “and” should not be read as requiring that each and every one of those items be present in the grouping, but rather should be read as “and/or” unless expressly stated otherwise. Similarly, a group of items linked with the conjunction “or” should not be read as requiring mutual exclusivity among that group, but rather should also be read as “and/or” unless expressly stated otherwise.

What is claimed is:

1. In frequency equalization, a received signals goes through frequency transform, the transformed signal is divided by a frequency transform of a channel response, a method for equalization comprising the step of:
adjusting a quotient of the division by a weight function, wherein the function varies under a set of conditions;
whereby for a frequency selective channel, deep fades are adjusted, and noise or interference are reduced.

2. The method of claim 1, wherein the method is used in a single carrier OFDM application.

3. The method of claim 1, wherein the method is used in a multi-carrier OFDM application.

4. In frequency equalization, a received signals goes through frequency transform, the transformed signal is divided by a frequency transform of a channel response, a receiver comprising a method for equalization comprising the step of:
adjusting a quotient of the division by a weight function, wherein the function varies under a set of conditions;
whereby for a frequency selective channel, deep fades are adjusted, and noise or interference are reduced.

5. The receiver of claim 4, wherein the receiver is used in a single carrier OFDM application.

6. The receiver of claim 4, wherein the receiver is used in a multi-carrier OFDM application.
